(19) United States
(12) Patent Application Publication
(10) Pub. No.: US 2023/0284457 A1
(43) Pub. Date: Sep. 7, 2023

(54) INTERCONNECTS WITH SPINTRONIC LOGIC DEVICES

(71) Applicant: Intel Corporation, Santa Clara, CA (US)

(72) Inventors: Hai Li, Portland, OR (US); Dmitri Evgenievich Nikonov, Beaverton, OR (US); Chia-Ching Lin, Portland, OR (US); Punyashloka Debashis, Hillsboro, OR (US); Ian Alexander Young, Olympia, WA (US); Julien Sebot, Portland, OR (US)

(73) Assignee: Intel Corporation, Santa Clara, CA (US)

(21) Appl. No.: 17/688,495

(22) Filed: Mar. 7, 2022

(51) Int. Cl. H01L 27/22; H01L 43/04; H01L 43/06

(52) U.S. Cl. CPC H01L 27/22; H01L 43/04; H01L 43/06

(57) ABSTRACT

In one embodiment, a first integrated circuit component, a second integrated circuit component, and an electrical interconnect coupling the first integrated circuit component and the second integrated circuit component. The interconnect comprises one or more spintronic logic devices.

### BACKGROUND

In typical complementary metal-oxide-semiconductor (CMOS)-based chips, signal repeaters are used for long-range interconnects (e.g., those on the order of millimeters) between components of the chip (e.g., between cache units and execution units of the chip). As data traffic across the chip becomes greater, the power consumption and the complexity of such interconnects are increasing rapidly.

### BRIEF DESCRIPTION OF THE DRAWINGS

FIG. 1A illustrates an integrated circuit structure including a set of example magnetoelectric spin orbit (MESO) logic devices connected to one another in a cascaded fashion in accordance with embodiments of the present disclosure.

FIG. 1B illustrates an equivalent circuit diagram of the cascaded MESO devices shown in FIG. 1A.

FIG. 2 illustrates an integrated circuit structure including an example ferroelectric spin orbit logic (FSOL) device in accordance with embodiments of the present disclosure.

FIG. 3 illustrates a perspective view of a layout of cascaded ferroelectric spin orbit logic (FSOL) circuit including two cascaded FSOL inverters in accordance with embodiments of the present disclosure.

FIG. 4 illustrates another example integrated circuit structure with two FSOL devices connected to one another in a cascaded fashion in accordance with embodiments of the present disclosure.

FIGS. 5A-5B illustrate example spintronic logic-based repeater circuits in accordance with embodiments of the present disclosure.

FIG. 6 illustrates a simplified block diagram of an example integrated circuit chip architecture for a processor device in accordance with embodiments of the present disclosure.

FIG. 7 illustrates example simulation data for CMOS- and MESO-based repeater circuits showing total delay and total energy consumption relative to a total length of an interconnect between the device of the repeater.

FIGS. 8A-8B illustrate simulation data for CMOS-based and MESO-based repeater circuits with a 1000 um interconnect length.

FIG. 9 is a top view of a wafer and dies that may be included in a microelectronic assembly, in accordance with any of the embodiments disclosed herein.

FIG. 10 is a cross-sectional side view of an integrated circuit device that may be included in a microelectronic assembly, in accordance with any of the embodiments disclosed herein.

FIG. 11 is a cross-sectional side view of an integrated circuit device assembly that may include a microelectronic assembly, in accordance with any of the embodiments disclosed herein.

FIG. 12 is a block diagram of an example electrical device that may include a microelectronic assembly, in accordance with any of the embodiments disclosed herein.

### DETAILED DESCRIPTION

In typical complementary metal-oxide-semiconductor (CMOS)-based chips, signal repeaters are used for long-range interconnects (e.g., those on the order of millimeters) between components of the chip (e.g., between cache units and execution units of the chip). As data traffic across the chip becomes greater, the power consumption and the complexity of such interconnects are increasing rapidly.

The repeaters used in the CMOS-based chip circuits may be implemented as cascaded inverters and placed after a certain distance along a wire so that the RC delay in a wire remains acceptable. To realize long-range signal propagation, multiple stages are typically required to span across the required distance. To assure a sufficiently small delay in a repeater, multi-fin and/or multiple stages of repeaters may be used to charge the wire faster if too many stages are used. However, as a result of this, the overall delay increases, more energy dissipated to transmit data, and the interconnect occupies more area on the chip. Thus, optimization is needed to find the right distance between stages. Further, as the clock frequency and the data rates increase in data intensive applications, the power consumption and design complexity of these circuits increases rapidly.

Accordingly, embodiments of the present disclosure may use a spintronic logic device as repeater instead of a typical CMOS inverter. Example spintronic logic devices may include logic device whose state is encoded based upon spin states of electrons, such as through a ferroelectric polarization or magnetization. The spintronics logic devices may charge/voltage driven and provide charge/voltage outputs. They may be switched by a magnetoelectric effect in certain instances, and the devices may produce an output signal (e.g., voltage) via a spin-orbit effect. Example spintronics logic devices include magnetoelectric spin orbit (MESO) logic devices or ferroelectric spin orbit logic (FSOL) devices, such as those described herein. In some embodiments, the spintronic logic device may be a differential input device, or may be a single input device.

Spintronic logic-based repeater circuits may provide one or more advantages over CMOS-based repeaters. For example, spintronic logic-based repeater circuits may result in a reduction in the number of devices per repeater stage. As another example, spintronic logic-based repeater circuits may significantly lower power consumption with minimal additional delay being added. Further, by using a spintronic logic-based repeater circuit, power supply voltages on the chip can be reduced (e.g., to 100 mV) resulting in ultra-low power operation. And instead of using multi-fin/multi-stage designs like in typical CMOS inverters, a single spintronic logic device can serve as a repeater. This can greatly improve the chip area usage and the design complexity. While spintronic logic circuits and interconnects may work at a slower clock rate, the decrease in the data throughput in a single-bit interconnect can be compensated by implementing wider interconnect busses (i.e., more bits).

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

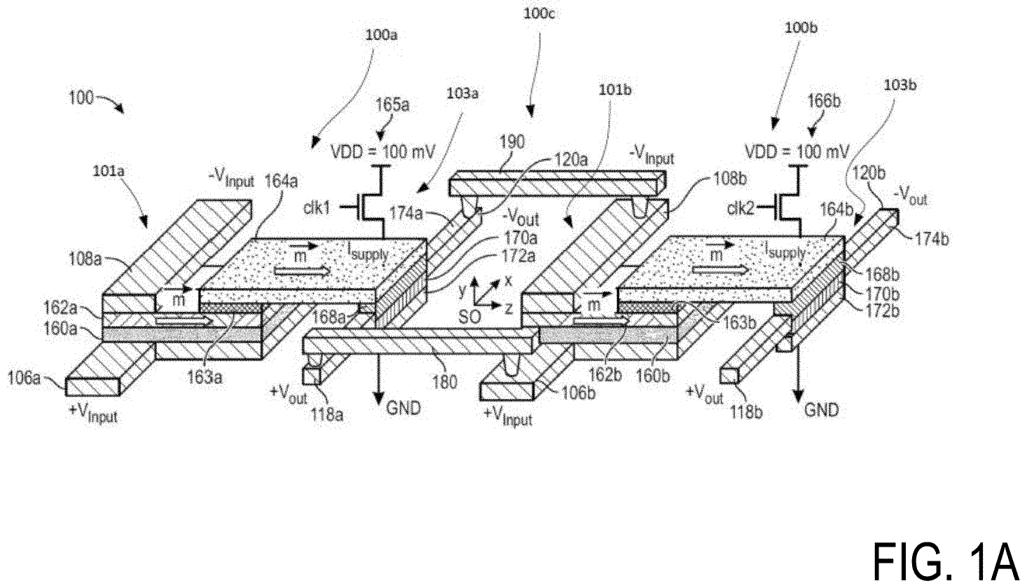

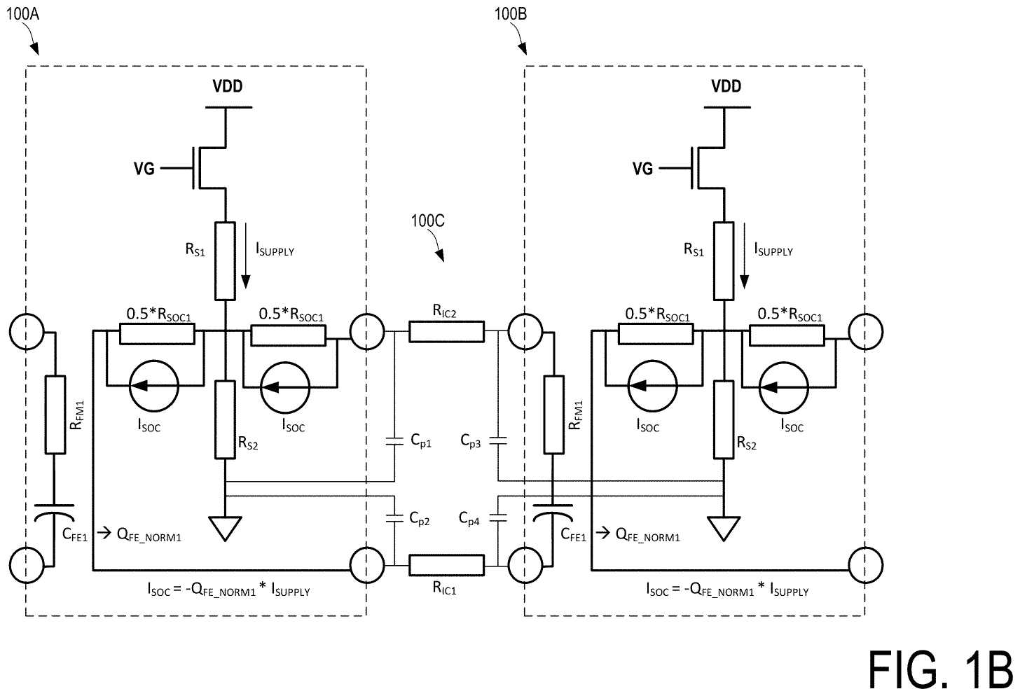

FIG. 1A illustrates an integrated circuit structure 100 including a set of example magnetoelectric spin orbit (MESO) logic devices 100a and 100b connected to one another in a cascaded fashion in accordance with embodiments of the present disclosure. An integrated circuit device assembly may include one or more of the integrated circuit structures of FIG. 1A and may further include a number of such MESO circuits cascaded with one another in the same manner as shown in FIG. 1A. The shown devices may be structurally identical to one another, and electrically connected by way of a non-magnetic electrical conductor bridge 100c including non-magnetic electrical conductors 180 and 190. The description provided below will therefore relate to either of MESO device 100a or 100b, and/or to their respective components, by referring to the same in the alternative as, for example, MESO device 100a/100b. In addition, in the description of FIG. 1A,“vertical” refers to the “y” direction, and “horizontal” refers to the “x” direction or the “z” direction, which directions are shown by way of the coordinate system provided in FIG. 1A.

MESO device 100a/100b includes a magnetoelectric (ME) capacitor region 101a/101b, and a spin orbit (SO) module region 103a/103b magnetically coupled together. The ME capacitor region 101a/101b includes two non-magnetic electrical conductors 106a/106b (which is to provide a positive input bias or voltage, Vin+) and 108a/108b (which is to provide a negative input bias or voltage, Vin−), between which are provided a layer including a magnetoelectric material (ME layer) 160a/160b connected to Vin−, and a layer including a first ferromagnetic material (FM layer) 162a/162b.

The ME capacitor 101a/101b may be charged and discharged by virtue of the bias applied between Vin+ and Vin−. A charging and discharging of the ME capacitor region corresponds to a change in the information state of the ME capacitor. The ME capacitor region 101a/101b is coupled to the SO module 103a/103b by way of a non-magnetic electrical conductor structure including non-magnetic electrical conductors 180 and 190.

SO module 103a/103b includes a second FM layer 164a/164b disposed directly on a spin orbit coupling stack (SOC stack) including spin coherent layer 168a/168b and spin orbital coupling layer 170a/170b. Spin coherent layer 168a/168b, which in turn is disposed directly on a spin orbital coupling layer 170a in contact with a SO module non-magnetic electrical conductor 172a. SO module 103a/103b provides a structure that, when subjected to a supply current I_{supply} supplied by way of a transistor, such as the N-type Metal-Oxide-Semiconductor Field-Effect (NMOS) transistor 166a/166b, first converts the supply current I_{supply} to a spin current by virtue of I_{supply} contacting second FM layer 164a, and thereafter converts the spin current to an output supply current flowing horizontally in the positive or negative x direction depending on the magnetization direction of second FM layer 164a. Output charge current Iₒᵤₜₚᵤₜ of MESO device 100a generates a bias between Vin− and Vin+ of cascaded MESO device 100b as shown.

Second FM layer 164a is coupled to the first FM layer 162a by virtue of a coupling layer 163a. Coupling layer may include one or more of Fe₃O₄, CoFe₂O₄, EuO, Fe₂O₃, Co₂O₃, Co₂FeO₄, Ni₂FeO₄, (Ni,Co)₁₊₂ₓTi1−xO₃, yttrium iron garnet (YIG)=Y₃Fe₅O₁₂, (MgAl_{0.5}Fe_{1.5}O₄, MAFO), or (NiAFO, NiAlₓFe₂₋ₓO₄). The coupling layer is to electrically insulate the ME capacitor from the SO module (especially because of separate clocking of cascaded MESO devices as suggested for example by first and second clocking signals clk1 and clk2) while providing magnetic coupling between the first FM layer 162a and the second FM layer 164a. Coupling layer 163a serves to isolate the ME capacitor from the SO module electrically, especially because of separately clocking of the MESO devices as noted above.

Transistor 166a/166b, clocked using a clock signal clk1/clk2 at its gate, is to provide the supply current I_{supply} by virtue of a bias between V_{dd} and Ground (Gnd) as shown. I_{supply} is supplied vertically, in the minus y direction, to second FM layer 164a/164b. I_{supply} will have no spin polarization before reaching the second FM layer. By virtue of contacting the second FM layer however, a spin current is generated from the supply current, the spin current having a spin direction based on a magnetization direction in the second FM layer. In FIG. 1A, magnetization direction is shown by way of arrows denoted “m.” The spin current will pass through the spin coherent layer 168a/168b and reach the interface between the spin coherent layer 168a/168b and the spin orbital coupling (SO coupling) layer 170a/170b. At the latter interface, the spin current will be converted into the output/spin orbital (SO) charge current I_{c} as shown. The SO charge current I_{c} flow creates a bias Vₒᵤₜ+ at contact 118a and a bias Vₒᵤₜ− at contact 120a.

Because of the magnetic coupling provided by the coupling layer 163a/163b, first FM layer 162a/162b and second FM layer 164a/164b will have magnetization directions that are the same when a bias is applied to the ME capacitor 100a/100b. The direction of magnetization m, in the shown configuration, will be in the negative or positive z direction, since, in general, and unless other factors are at play, a magnetization direction in an object tends to be along a direction corresponding to a longest dimension of the object, in the shown case, in the z direction. When the magnetization direction m is changed, the functionality of the SO module is changed as well. As a result, with a change in the direction of magnetization of BML and TML, the direction of the SO charge current I_{c} can change as well. Therefore, changing the ME capacitor state will change the direction of the SO charge current I_{c}.

SO module 103a/103b operates based on spintronic phenomena, including a spin hall effect (SHE) and/or a Rashba-Edelstein effect (including inverses of each of the latter effects). SHE is based on the use of heavy metals to convert a spin current into a charge current, and vice versa in the inverse case.

Referring to the SO module 103a/103b, in the case of inverse SHE, I_{supply} going into the second FM layer 164a/164b will polarize the electrons of the supply current I_{supply} and generate a spin polarized current therefrom, where the spin movement of the electrons is based on the direction of magnetization m. Therefore, the SO module 103a/103b is configured to convert the magnetization state of the FM layers into a SO charge current I_{c}.

The current I_{c} can serve to charge a capacitor in the next cascaded MESO device by virtue of the generation of a voltage bias between contacts 118a and 120a as shown. Furthermore, it is to be understood that each of the MESO device shown, including 100b, can be used to charge a ME capacitor similar to ME capacitor 101a/101b at the next cascaded MESO device by virtue of the SO charge current I_{c} that it may generate and the resultant output voltage bias (e.g., at contacts 118b and 120b of MESO device 100b) at its output to form the logic circuit or part of a logic circuit, as shown in FIG. 1A.

FIG. 1B illustrates an equivalent circuit diagram of the cascaded MESO devices 100a/100b shown in FIG. 1A. In the example shown, the resistances R_{IC1} and R_{IC2} represent the inherent resistance of an interconnect between the differential inputs and outputs of the MESO devices (e.g., 180/190 in FIG. 1A). The value of R_{IC1} and R_{IC2} may generally scale with the length of the interconnect on the chip. In addition, as shown, there is also parasitic capacitance C_{pN} between the input/output nodes and the ground or adjacent wires.

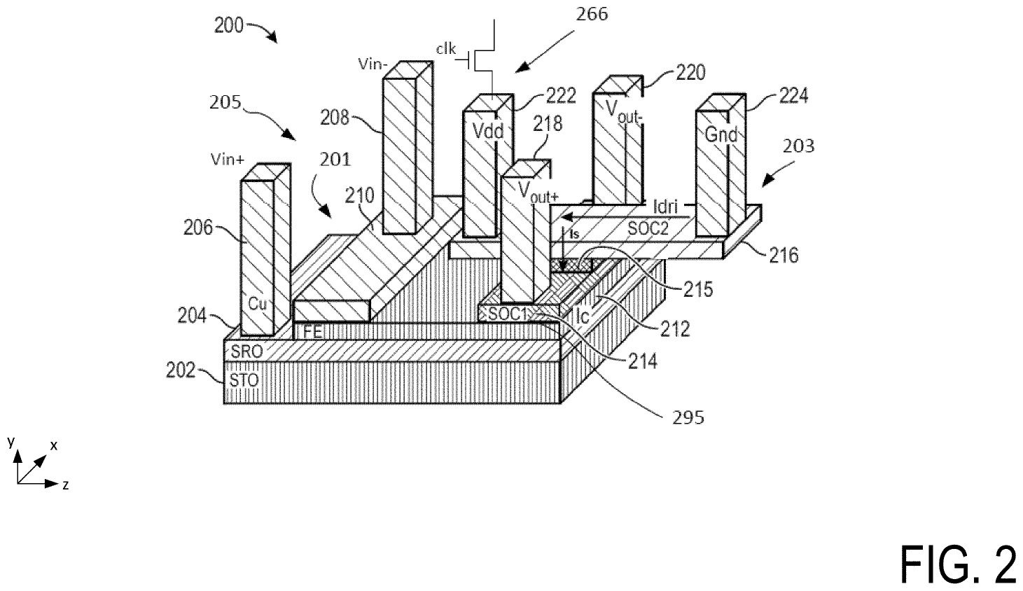

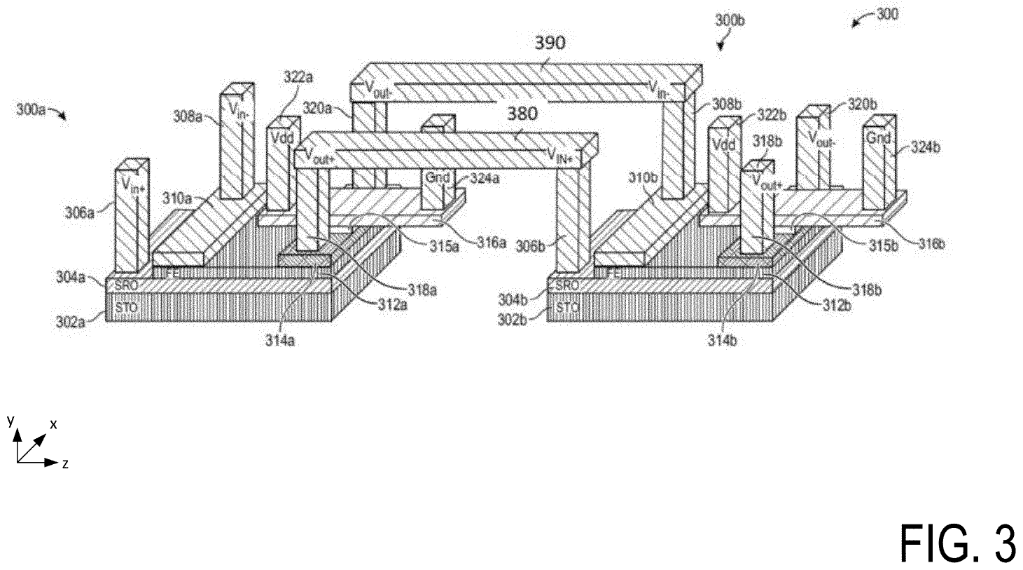

FIG. 2 illustrates an integrated circuit structure 200 including an example ferroelectric spin orbit logic (FSOL) device 205 in accordance with embodiments of the present disclosure. The FSOL device 200 may be configured to be electrically connected by way of a non-magnetic electrical conductor bridge to another similar or identical device in a cascaded fashion, as will be explained in further detail in the context of FIG. 3. In the description of FIG. 2, “vertical” refers to the “y” direction, and “horizontal” refers to the “x” direction or the “z” direction, which directions are shown by way of the coordinate system provided in FIG. 2.

FSOL device 200 includes a ferroelectric (FE) capacitor 201, and a spin orbit module (SOM) region 203 coupled together by virtue of an interface 295 between a layer of capacitor 201 including a ferroelectric (FE) material (FE layer) 212 and a first layer including a spin orbit coupling (SOC) material (SOC1 layer) 214 at the SOM region 203. The FE layer 212 may include a material such as at least one of BiFeO3, BaTiO3, Pb[ZrₓTi₁₋ₓ]O3, LuFeO3, or HfZrOx. The FE capacitor 201 includes the FE layer 212, a negative electrode layer 210 that is connected to a negative input contact Vᵢₙ−208, and a positive electrode layer that corresponds to a layer including SrRuO3 (SRO layer) 204. SRO layer 204 is connected to a positive input Vᵢₙ+ conductive structure 206. Contacts Vᵢₙ+ and Vᵢₙ− are to provide a bias differential at each side of the FE layer 212. SRO layer 204 may be grown epitaxially onto a layer including silicon (Si) substrate buffered by SrTiO3 (STO) layer 202. since the FE material choice is greatly increased by embodiments, the bottom electrode including the SRO/STO layers can be replaced by many other material substrates or conducting materials compatible with various FE materials. The SRO layer or STO layer may include, for example, at least one of SrRuO3, SrVO3, SrCrO3, SrFeO3, ReO3, NaWO3, KMoO3, SrNbO3, LaTiO3, LaWO3. Non-stoichiometric as well as doped materials are also possible.

The FE capacitor 201 may be charged and discharged by virtue of the bias applied between Vᵢₙ+ and Vᵢₙ−. A charging and discharging of the FE capacitor corresponds to a change in the information state of the FE capacitor by virtue of a change in electric polarization within the FE material of FE layer 212. The FE capacitor 201 is coupled to the SOM 203 by way of an interface between FE layer 212 and SOC1 layer 214, where FE layer 212 and SOC1 layer 214 are coupled to one another such that an electric polarization direction of the FE layer 212 affects a direction of current flow I_{c} within the SOC1 layer as will be explained further below.

SOM 203 in turn includes a spin orbit coupling stack (SOC stack) that in turn comprises a first layer including a SOC material (SOC1 layer) 214, a second layer including a SOC material (SOC2 layer) 216, and a layer including a material to serve as a tunnel barrier (TB layer) 215, such as MgO or AlOx, or the like, between SOC1 layer 214 and SOC2 layer 216. Any of the SOC1 layer or SOC2 layer may include any of: a metal, such as W, Ta, or Pt; topological insulators such as Bi₂Se₃, BiSb; or materials containing 2-dimensional electron gas e.g. LaAlO3/SrTiO3 or Al/KTaO3 interfaces. As used herein, a “SOC material” is a material that has a spin Hall effect coefficient.

In some embodiments, either of SOC1 layer or SOC2 layer may comprise one or more layers. For example, either of SOC1 layer or SOC2 layer may comprise a SOC material, or a hetero-structure, which is characterized by being able to provide a Spin Hall effect or an inverse Spin Hall effect (SHE or inverse SHE). In some embodiments, either of SOC1 layer or SOC2 layer may comprise two-dimensional materials (2D) with spin orbit interaction. According to some embodiments, the first SOC material and the second SOC material are different from one another. According to some other embodiments, the first SOC material and the second SOC material are identical to one another.

In some embodiments, the 2D materials may be selected from a group consisting of: Graphene, MoS₂, WSe₂, WS₂, and MoSe₂ In some embodiments, the 2D materials include an absorbent selected from a group consisting of: Cu, Ag, Pt, Bi, Fr, and H absorbents.

In some embodiments, either of SOC1 layer or SOC2 layer may include materials ROCh₂, where ‘R’ is selected from a group consisting of: La, Ce, Pr, Nd, Sr, Sc, Ga, Al, and In, and where “Ch” is a chalcogenide selected from a group consisting of S, Se, and Te.

In some embodiments, either of SOC1 layer or SOC2 layer may include one or more material that form a hetero-structure with Cu, Ag, Al, and Au.

In some embodiments, either of SOC1 layer or SOC2 layer comprises a material selected from a group consisting of: β-Ta, β-W, W, Pt, Cu doped with Iridium, Cu doped with Bismuth, and Cu doped an element of 3d, 4d, 5d, 4f, or 5f of periodic table groups.

In some embodiments, either of SOC1 layer or SOC2 layer may include any combination of one or more layers of the materials described above in the context of SOC layers.

Any of the SOC1 layer and SOC2 layer may include one layer or multiple layers. The FE layer or TB layer may include a single layer. The FE layer may for example have a thickness of about 10 nm or less. The TB layer may be a few nm thicker than the FE layer. The layers do not have to have a rectangular cross section, and may have any cross section. For example, they can have rounded corners with similar functionality to that for rectangular cross sections.

In some embodiments, the spin-orbit mechanism responsible for spin-to-charge current conversion, such as that implemented by way of example spin orbit stack including layers 168a, 170a and 172a of FIG. 1A, or such as that exhibited by SOC1 layer 214 of FIG. 2 described herein, is referred to as the inverse Spin Hall effect in a 2D electron gases.

For example, referring first to FIG. 2 and SOC2 layer 216, positive current I_{dri} along the −z direction produces a spin injection current Iₛ with transport direction for the spin along the −y direction and spins pointing to the +y direction, as expressed in Equation (1) below.

Îₛ=θ· [symbol] ·\hat{σ} Eq. (1)

where θ is the spin Hall angle, and σ is the spin operator, which stands for spin polarization, a unitless quantity.

The above results in the generation of charge current I_{c} in SOC1 layer 214 proportional to the spin current Iₛ (the propagation of the spin without charge flow).

The spin-orbit interaction at an interface between SOC1 layer and SOC2 layer is brought about by the inverse Rashba-Edelstein Effect (IREE)) as referred to above (inverse SHE), producing a charge current I_{c} in the horizontal direction given as:

Î_{c}=θ·Îₛ·\hat{σ} Eq. (3)

A mechanism of embodiments is to use the local electrical field generated by FE at the FE/SOC1 interface. This local electrical field will change the sign of θ, so that the current directionality of I_{c} will change based on the FE polarization state.

Referring still to FIG. 2, the TB layer 215 may include one or more layers of a dielectric oxide material, such as manganese oxide MgO, which is good at preserving the spin polarization, although other materials, such as, for example, aluminum oxide Al₂O₃ and silicon oxide SiO work as well. TB layer 215 may be in direct contact with SOC1 layer 214 at one side thereof, and with SOC2 layer at another side thereof. A role of TB layer 215 is to provide electrical isolation between SOC1 layer 214 and SOC2 layer 215. SOC1 layer 214 is coupled at one end thereof to a positive output contact Vₒᵤₜ+218, and at another end thereof to a negative output contact Vₒᵤₜ−220. Vₒᵤₜ− and Vₒᵤₜ+ in FIG. 2 may correspond to the Vₒᵤₜ− 120a and Vₒᵤₜ+118a of FIG. 1A that may be connected to another FSOL device similar to FSOL device 200 by virtue of a bridge similar to bridge 100c of FIG. 1A as will be described in further detail in connection with FIG. 3 below.

SOM 203 provides a structure that, when subjected to a drive/supply current I_{dri}, for example supplied by way of a transistor, such as the N-type Metal-Oxide-Semiconductor Field-Effect (NMOS) transistor 266 similar to NMOS transistor 166a of FIG. 1A, first converts the supply current I_{dri} to a spin current Iₛ by virtue of I_{supply} contacting SOC2 layer 216, and thereafter converts the spin current Iₛ to an output supply current I_{c} flowing horizontally in the positive or negative x direction in SOC2 layer 214 depending on the electric polarization direction within FE layer 212. Output charge current I_{c} of FSOL device 200 generates a bias between Vₒᵤₜ+ and Vₒᵤₜ− and results in a similar bias in a cascaded FSOL device as will be explained in the context of FIG. 3 below.

Transistor 266, clocked using a clock signal clk at its gate, is to provide the drive current I_{dri} by virtue of a bias between V_{dd} at V_{dd} conductive structure 222 and Ground (Gnd) at Gnd conductive structure 224 as shown. As shown I_{dri} is supplied horizontally along SOC2 layer 216 between Gnd conductive structure 224 and V_{dd} conductive structure 222, in the minus z direction although embodiments are not so limited and the Gnd and V_{dd} contacts could be switched in their positions to have I_{dri} flow in the plus z direction. By virtue of contacting the SOC2 layer 216, a spin current Iₛ is generated from I_{dri}, the spin current Iₛ having a spin direction as dictated by the SOC2 layer 216. Spin current Iₛ will pass through the TB layer 215, and reach the interface 295 between the FE layer 212 and the SOC1 layer 214. At the latter interface, the spin current will be converted into the output/spin orbital (SO) charge current I_{c} as shown.

The direction of electric polarization in the FE layer 212 (controlled by the polarity of voltage (delta of Vin+ and Vin− across the FE layer) in the plus or minus y direction) will change the functionality of the SOM 203 by affecting the direction of flow of I_{c} within SOC1 layer. The direction of electric polarization in the FE layer 212 specifically influences the functionality of SOC1 layer 214 by virtue of the interface 295 between FE layer 212 and SOC1 layer 214, while SOC2 layer 216 is insulated from the direction of electric polarization in the FE layer 212 by virtue of TB layer 215. As a result, with a change in the direction of electric polarization of FE layer 212, the direction of the SO charge current I_{c} can change as well. Therefore, changing the FE capacitor state will change the direction of the SO charge current I_{c}.

While, in the embodiment of FIG. 1A, the bias between Vᵢₙ− and Vᵢₙ+ would polarize the magnetic properties of the ME layer 160a, which in turn would affect the magnetization direction of the FM layers 162a and 164a, in the embodiment of FIG. 2, we do away with a magnetoelectric layer, the two FM layers 162a and 164a, and the coupling layer 163a therebetween, Instead, using FE capacitor 201, we polarize the FE layer 212 instead, without using a manipulation of magnetization direction in a FM layer. The electric field, as reflected in the direction of electric polarization in FE layer 121, would impinge on interface 295 with SOC1 layer 214, and influence/change the spin orbit coupling effect of the SOC1 material. Therefore, the embodiment of FIG. 2 involves spintronics without magnetics.

In some embodiments, such as those described above in FIG. 2, and to be described below in the context of FIG. 3, the contacts, electrodes, interconnects, and non-magnetic conductors may be formed of non-magnetic metal (e.g., Cu, Ag, etc.).

FIG. 3 illustrates an integrated circuit structure 300 including a cascaded FSOL logic circuit having a set of FSOL devices 300a and 300b electrically connected to one another in a cascaded fashion as shown. The FSOL devices 300a and 300b may be similar to the FSOL device 200 of FIG. 2. The shown devices may, similar to the cascaded arrangement of FIG. 1A, be structurally identical to one another, and electrically connected by way of a non-magnetic electrical conductor bridge 300c including non-magnetic electrical conductors 380 and 390. The description provided above regarding FIG. 2 will therefore relate to either of FSOL devices 300a or 300b of FIG. 3, and/or to their respective components, with the difference being that a component with a reference numeral “x” in FIG. 2 is denoted “xa” for FSOL device 300a of FIG. 3, and “xb” for FSOL device 300b of FIG. 3. In addition, in the description of FIG. 3, similar to that of FIGS. 1 and 2, “vertical” refers to the “y” direction, and “horizontal” refers to the “x” direction or the “z” direction, which directions are shown by way of the coordinate system provided in FIG. 3.

In FIG. 3, the charge current I_{c} from FSOL device 300a (similar to FSOL device 200 of FIG. 2) may be carried by conductor bridge 300c in FIG. 3, which bridge includes conductors 380 and 390, similar to conductors 180 and 190 of bridge 100c of FIG. 1A. I_{c} can serve to charge a capacitor in the next cascaded FSOL device 300b by virtue of the generation of a voltage bias between contacts 318a and 320a as shown. Furthermore, it is to be understood that each of the FSOL device shown, including d00b, can be used to charge a capacitor similar to capacitor 201 of FIG. 2 at the next cascaded FSOL device by virtue of the SO charge current I_{c} that it may generate and the resultant output voltage bias (e.g. at contacts 318b and 320b of FSOL device 300b) at its output to form the logic circuit or part of a logic circuit, as shown in FIG. 3.

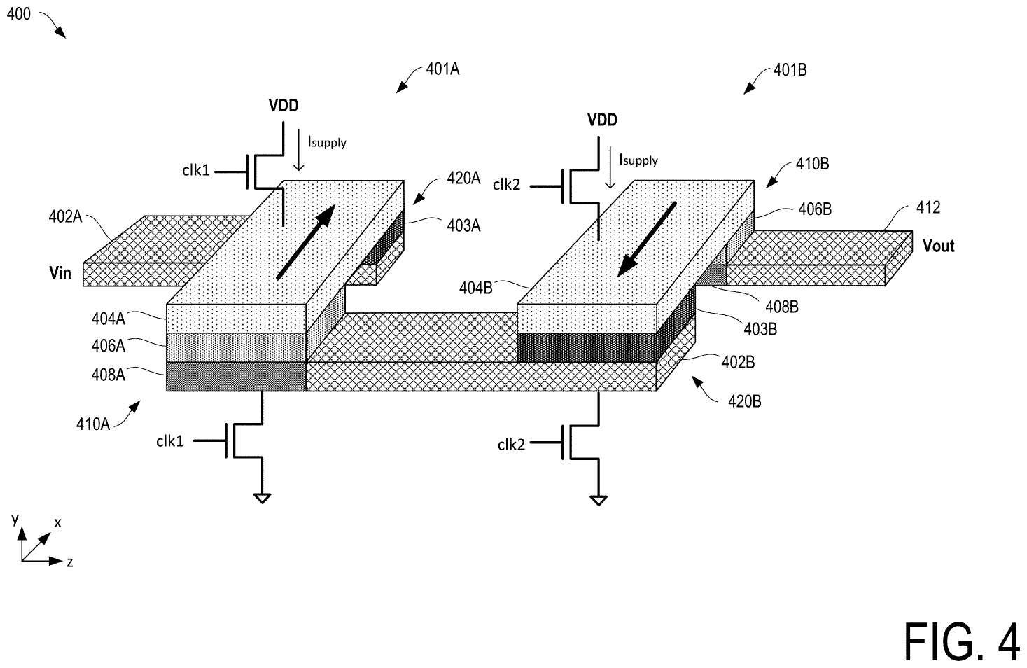

FIG. 4 illustrates another example integrated circuit structure 400 with two single input spintronic logic devices 401a/401b connected to one another in a cascaded fashion in accordance with embodiments of the present disclosure. The example spintronic logic devices 401 are single input devices, whereas the spintronic logic shown in FIGS. 1A, and 2-3 are differential input devices. The shown devices may be structurally identical to one another. The description provided below will therefore relate to either of spintronic logic device 401a or 401b, and/or to their respective components, by referring to the same in the alternative as, for example, spintronic logic device 401a/401b. In addition, in the description of FIG. 4,“vertical” refers to the “y” direction, and “horizontal” refers to the “x” direction or the “z” direction, which directions are shown by way of the coordinate system provided in FIG. 1A.

Each spintronic logic device 401 includes a spin orbital (SO) module region 410a/b and a magnetoelectric (ME) capacitor region 420a/b. The SO module region 410a/b includes a stack of materials that include a spin orbit coupling (SOC) material layer 408a/b, a spin coherent (SC) material layer 406a/b above the SOC layer 408a/b, and a ferromagnetic (FM) material layer 404a/b above the SC material layer 406a/b. The ME capacitor region 420a/b includes a stack of materials that includes a non-magnetic metal material layer 402a/b, a magnetoelectric (ME) material layer 403a/b above the non-magnetic metal material layer 402a/b, and the FM material layer 404a/b above the ME material layer 403a/b. In the example devices, spins injected from the ferromagnet (FM) material layer 403a/b in the vertical direction with spin polarization along the in-plane direction cause a topologically generated charge current in the SOC material layer 408a/b. Injecting a spin current polarized along the in-plane direction overpopulates the Fermi surface on one side of the topological material compared to the other side, generating a net charge current in the z direction. The conversion has the right symmetry to convert the information of the FM material layer to a current output. Thus, the state of the devices 401a/b can be encoded based on the magnetization of the FM material layers.

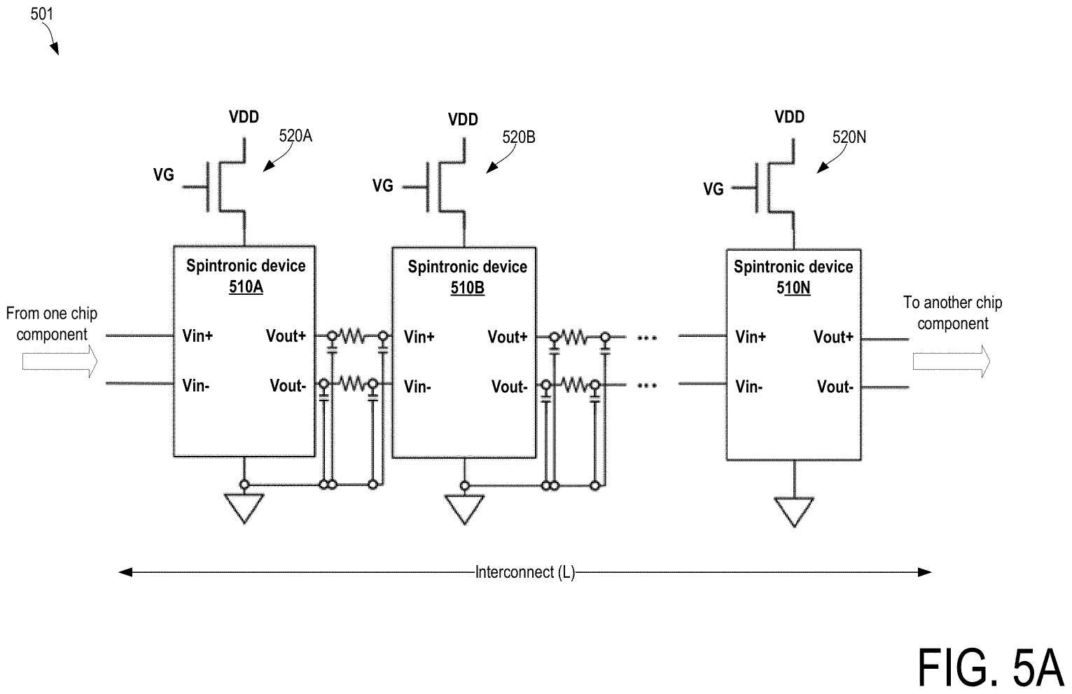

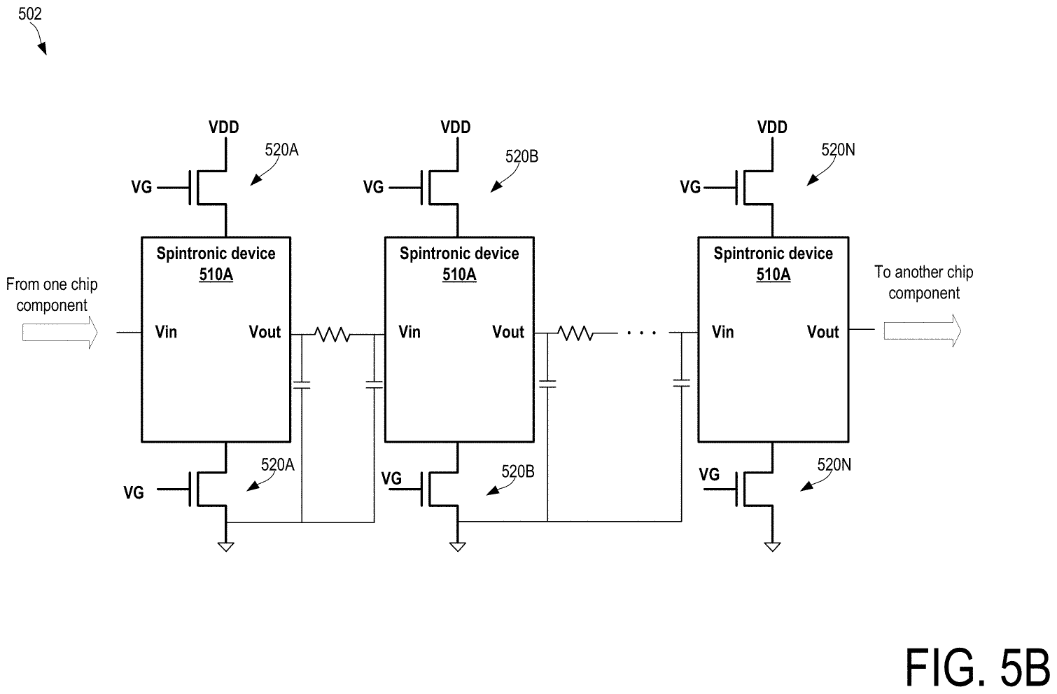

FIGS. 5A-5B illustrate example spintronic logic-based repeater circuits 501, 502 in accordance with embodiments of the present disclosure. In particular, the repeater circuit 501 includes differential input spintronic logic devices, such as those described above with respect to FIGS. 1A-3, and the repeater circuit 502 includes single input spintronic logic device, such as the devices described above with respect to FIG. 4. Other types of spintronic logic devices may be used in the examples shown as well. Each repeater circuit 501, 502 includes a number N of cascaded spintronic logic devices 510 on an interconnect of length L between components of an integrated circuit chip. Further, each repeater circuit includes one or more n-channel metal oxide semiconductor (nMOS) transistors 520 activated by an applied gate voltage V_{G} to provide a supply current (e.g., I_{SUPPLY} as shown in FIG. 1A-1B) to the spintronic logic devices 510. The nMOS transistors 520 of the circuits 501, 502 may remain on throughout operation, or each nMOS transistor 520 may be selectively turned on and off by applying clocking pulses to their gates, which may allow for additional energy savings.

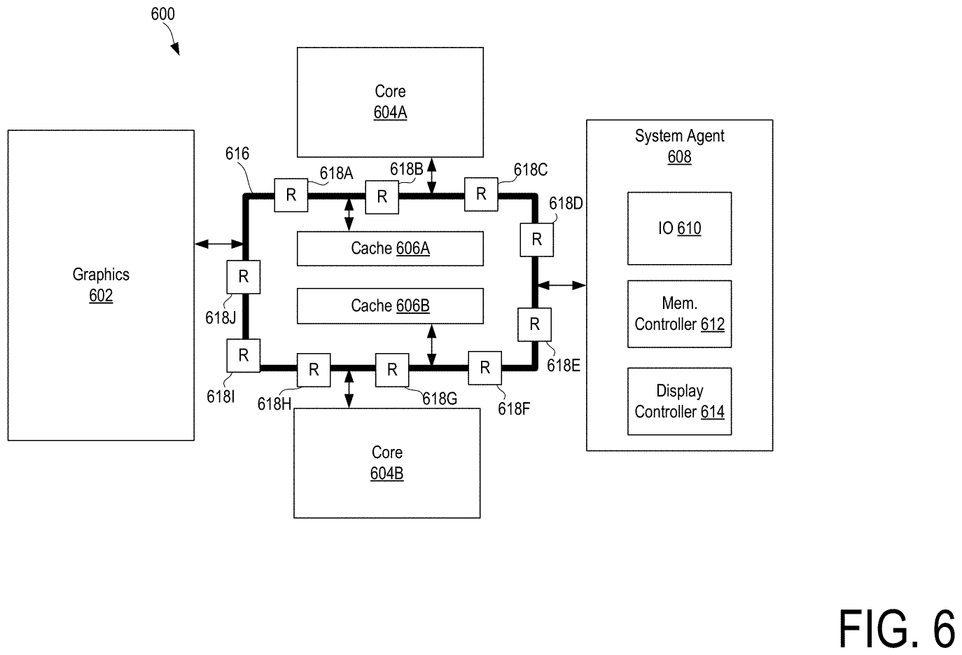

FIG. 6 illustrates a simplified block diagram of an example integrated circuit chip architecture 600 for a processor device in accordance with embodiments of the present disclosure. The example architecture 600 includes graphics processing circuitry 602, two processing cores 604, cache units 606, and a system agent 608, which includes input-output (10) circuitry 610, memory controller circuitry 612, and display controller circuitry 614, connected to one another via a ring interconnect 616. The architecture 600 may include additional, fewer, or other components than those shown. The graphics processing circuitry 602, the processing cores 604, or both may include logic implemented by CMOS devices, MESO devices, or a combination thereof. In the example shown, the interconnect 616 includes a number of repeaters 618 between components of the architecture 600. The repeaters 618 may be implemented as MESO devices as described above. Any suitable number of repeaters may be used between components of the integrated circuit chip architecture 600, and the number may be determined based on the interconnect length between the components of the architecture 600. In some instances, an analysis may be performed using data similar to the simulation data 520 to determine a number of MESO devices to include as repeaters between components of the architecture 600.

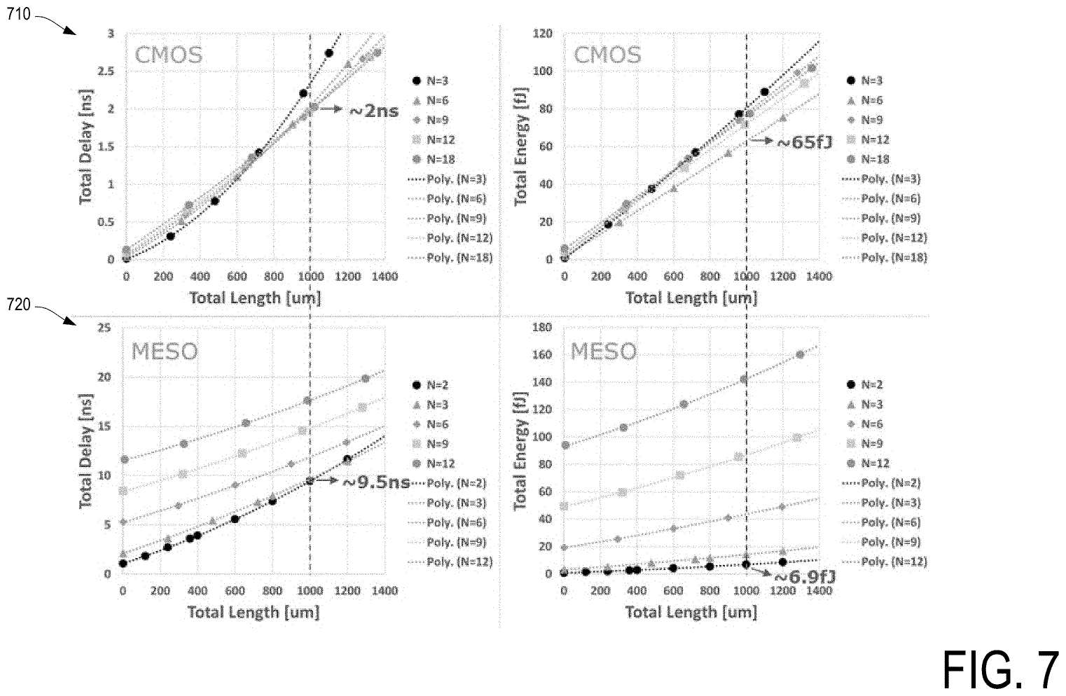

FIG. 7 illustrates example simulation data 710, 720 for CMOS- and MESO-based repeater circuits, respectively. In particular, the simulation data show a total delay and total energy consumption relative to a total length of an interconnect between chip components. As shown, the total delay data refer to a total delay time for information to pass through a number N of the devices in the repeater circuit. For instance, where N=2 CMOS devices (i.e., inverters) or N=2 MESO devices, the total delay refers to the delay time for information to pass through the two devices. Similarly, the total energy consumption data refers to a total energy consumption of all the devices in the circuit.

As shown in the simulation data, for an interconnect length of 1000 um (i.e., 1000 um between chip components), the interconnects with MESO-based repeater circuits are approximately 10× more energy efficient compared to the interconnects with CMOS-based repeater circuits. While the CMOS-based repeater circuits have a shorter delay, they also require more “stages” (which may refer to the number of inverters used on the interconnect length). For instance, in the example shown, the CMOS-based repeater circuit with N=6 inverter stages gives approximately 2 ns total delay and approximately 65fJ total energy consumption at an interconnect length of 1000 um. In contrast, a MESO-based repeater circuit with N=2 MESO devices gives approximately 9.5 ns total delay and approximately 6.9fJ energy consumption at the same interconnect length of 1000 um. Thus, fewer MESO devices may be needed for the same interconnect length versus CMOS devices. While longer delays are noted with the MESO-based repeater circuits, such delay may be tolerated, especially where other components of the integrated circuit (e.g., processor cores) are also implementing MESO devices as well.

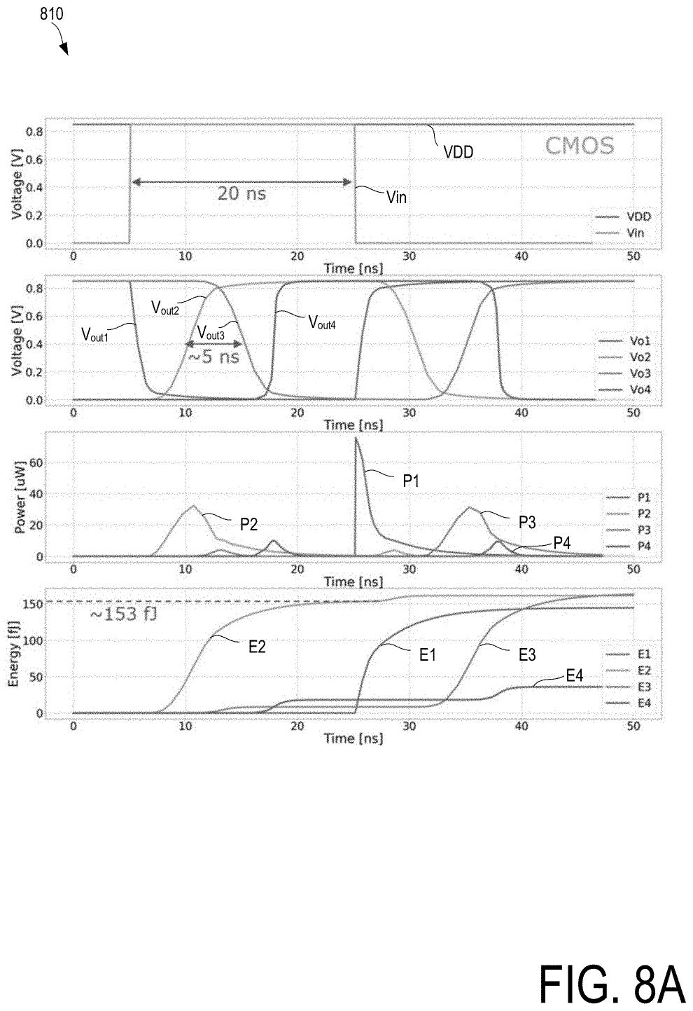

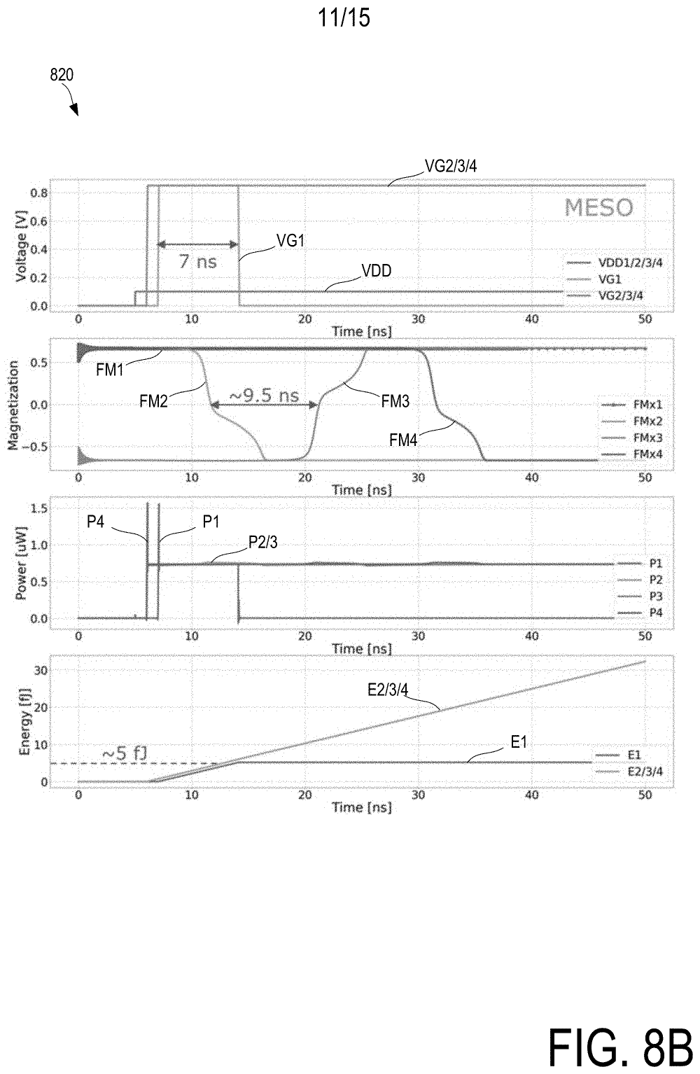

FIGS. 8A-8B illustrate simulation data 810, 820 for CMOS- and MESO-based repeater circuits, respectively, with a 1000 um interconnect length. In particular, the simulation data 810, 820 relate to an example repeater circuit that includes N=4 devices. The first plot of the simulation data 810A shows a VDD and Vin voltages over time, the second plot shows output voltages at each CMOS inverter of the circuit over time, the third plot shows power consumption for each CMOS inverter of the circuit over time, and the fourth plot shows an energy consumption by each CMOS inverter over time. The first plot of the simulation data 700 shows a VDD and gate voltages for each supply nMOS transistor over time, the second plot shows magnetizations of each MESO device of the circuit over time, the third plot shows power consumption for each MESO device of the circuit over time, and the fourth plot shows an energy consumption by each MESO device over time.

As shown, in the CMOS-based repeater circuit, an input pulse is provided with a pulse width of 20 ns and magnitude of 0.8 V (the same as VDD in this example). As shown in the second plot of FIG. 8A, the CMOS-based repeater circuit shows approximately 5 ns delay between each CMOS inverter (providing an approximate total delay of 20 ns) and has approximately 153fJ energy consumption by each CMOS inverter. By comparison, as shown in FIG. 8B, a MESO-based repeater circuit may reduce an input pulse width to 7 ns to reduce energy consumption. Additionally, the MESO-based repeater circuits may utilize a lower VDD than the CMOS-based repeater circuits (0.1V versus 0.8V), which may further aid in energy savings. As a result, the MESO-based repeater circuit shows approximately 9.5 ns delay between each MESO device (approximately 38 ns total delay) and approximately 5fJ energy consumption for each MESO device (that can be turned off selectively, since the driving current for the MESO-based repeater circuits can be turned off earlier as long as the switching energy barrier is cleared). This amounts to approximately 30× in energy savings with only approximately 2× increase in the delay.

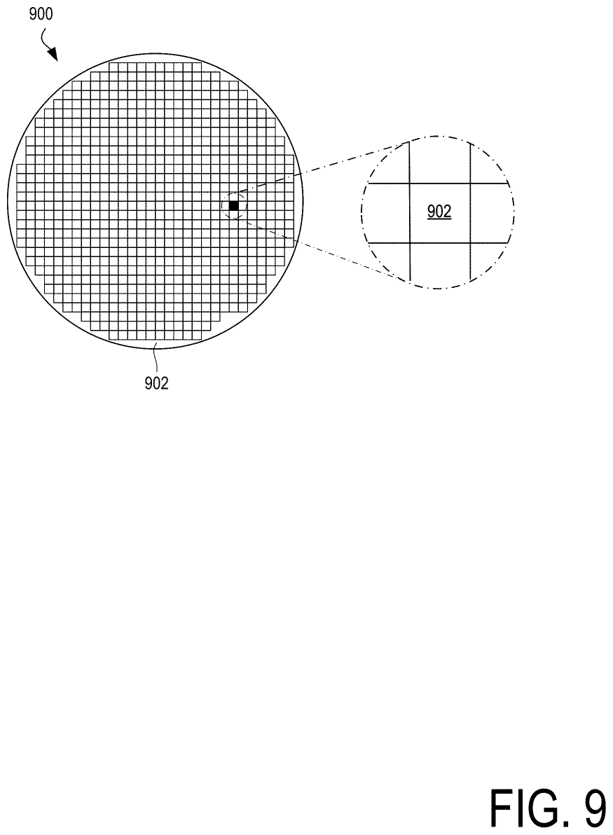

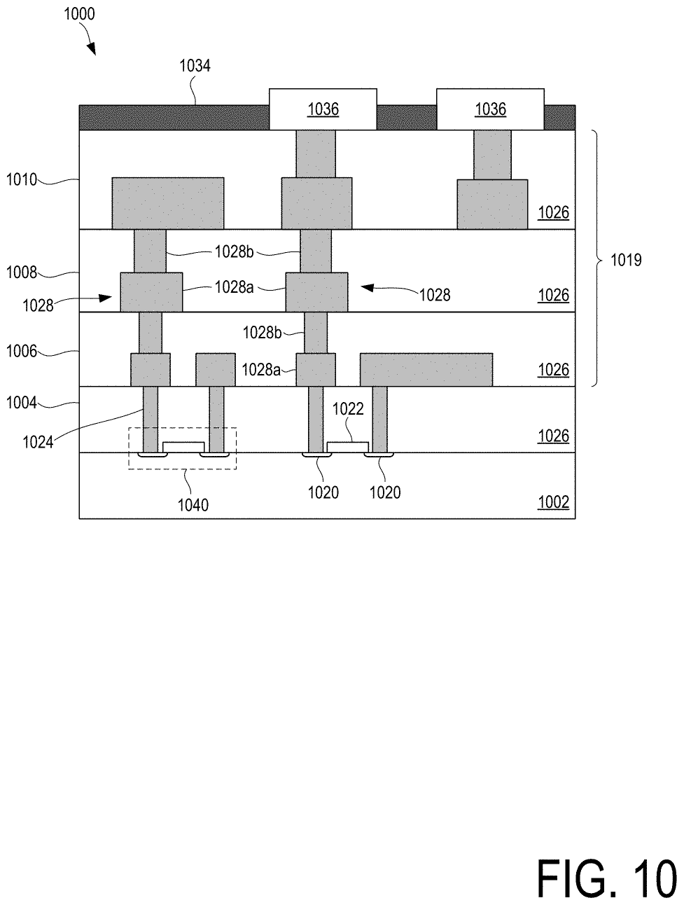

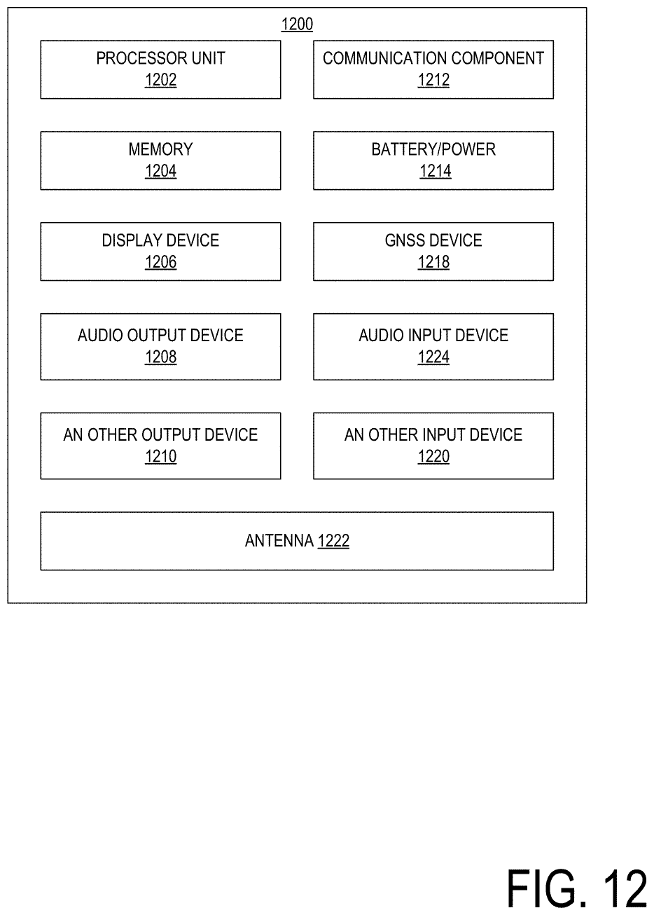

FIG. 9 is a top view of a wafer 900 and dies 902 that may incorporate any of the embodiments disclosed herein. The wafer 900 may be composed of semiconductor material and may include one or more dies 902 having integrated circuit structures formed on a surface of the wafer 900. The individual dies 902 may be a repeating unit of an integrated circuit product that includes any suitable integrated circuit. After the fabrication of the semiconductor product is complete, the wafer 900 may undergo a singulation process in which the dies 902 are separated from one another to provide discrete “chips” of the integrated circuit product. The die 902 may include one or more transistors (e.g., some of the transistors 1040 of FIG. 10, discussed below), supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 902. For example, a memory array formed by multiple memory devices may be formed on a same die 902 as a processor unit (e.g., the processor unit 1202 of FIG. 12) or other logic that is configured to store information in the memory devices or execute instructions stored in the memory array.

FIG. 10 is a cross-sectional side view of an integrated circuit device 1000 that may be included in any of the embodiments disclosed herein. One or more of the integrated circuit devices 1000 may be included in one or more dies 902 (FIG. 9). The integrated circuit device 1000 may be formed on a die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit device 1000 may be used. The die substrate 1002 may be part of a singulated die (e.g., the dies 902 of FIG. 9) or a wafer (e.g., the wafer 900 of FIG. 9).

The integrated circuit device 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 10, a transistor 1040 may include a gate 1022 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may consist of a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit device 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuit devices having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page from the perspective of FIG. 10. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit device 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit device 1000 with another component (e.g., a printed circuit board). The integrated circuit device 1000 may include additional or alternate structures to route the electrical signals from the interconnect layers 1006-1010; for example, the conductive contacts 1036 may include other analogous features (e.g., posts) that route the electrical signals to external components.

In some embodiments in which the integrated circuit device 1000 is a double-sided die, the integrated circuit device 1000 may include another metallization stack (not shown) on the opposite side of the device layer(s) 1004. This metallization stack may include multiple interconnect layers as discussed above with reference to the interconnect layers 1006-1010, to provide conductive pathways (e.g., including conductive lines and vias) between the device layer(s) 1004 and additional conductive contacts (not shown) on the opposite side of the integrated circuit device 1000 from the conductive contacts 1036.

In other embodiments in which the integrated circuit device 1000 is a double-sided die, the integrated circuit device 1000 may include one or more through silicon vias (TSVs) through the die substrate 1002; these TSVs may make contact with the device layer(s) 1004, and may provide conductive pathways between the device layer(s) 1004 and additional conductive contacts (not shown) on the opposite side of the integrated circuit device 1000 from the conductive contacts 1036. In some embodiments, TSVs extending through the substrate can be used for routing power and ground signals from conductive contacts on the opposite side of the integrated circuit device 1000 from the conductive contacts 1036 to the transistors 1040 and any other components integrated into the die 1000, and the metallization stack 1019 can be used to route I/O signals from the conductive contacts 1036 to transistors 1040 and any other components integrated into the die 1000.

Multiple integrated circuit devices 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

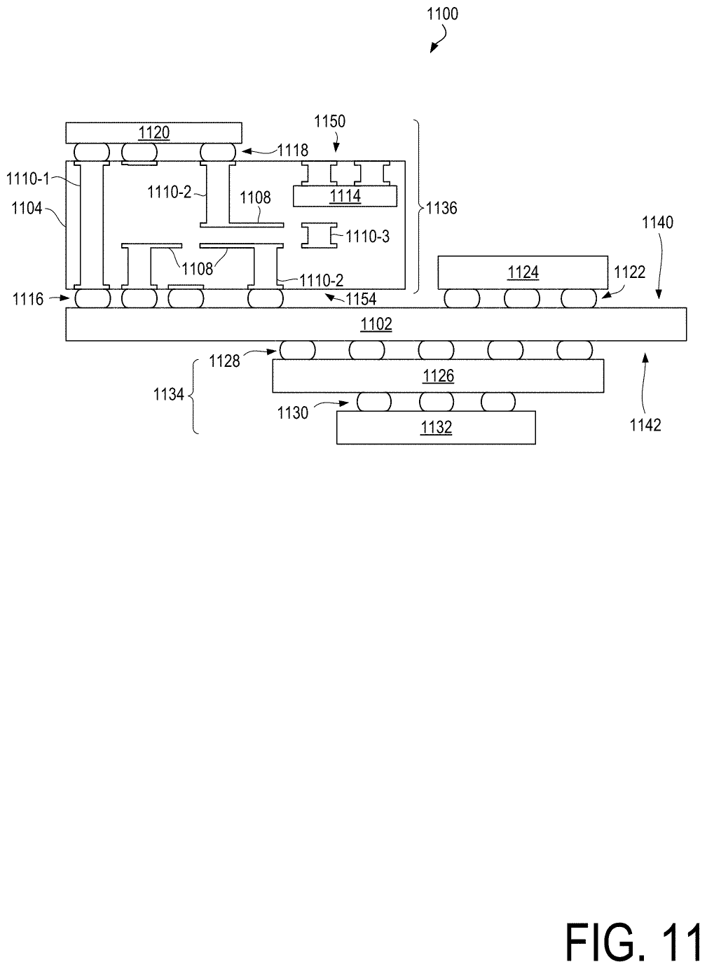

FIG. 11 is a cross-sectional side view of an integrated circuit device assembly 1100 that may include any of the embodiments disclosed herein. The integrated circuit device assembly 1100 includes a number of components disposed on a circuit board 1102 (which may be a motherboard, system board, mainboard, etc.). The integrated circuit device assembly 1100 includes components disposed on a first face 1140 of the circuit board 1102 and an opposing second face 1142 of the circuit board 1102; generally, components may be disposed on one or both faces 1140 and 1142.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1102. In other embodiments, the circuit board 1102 may be a non-PCB substrate. The integrated circuit device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1136 may include an integrated circuit component 1120 coupled to an interposer 1104 by coupling components 1118. The coupling components 1118 may take any suitable form for the application, such as the forms discussed above with reference to the coupling components 1116. Although a single integrated circuit component 1120 is shown in FIG. 11, multiple integrated circuit components may be coupled to the interposer 1104; indeed, additional interposers may be coupled to the interposer 1104. The interposer 1104 may provide an intervening substrate used to bridge the circuit board 1102 and the integrated circuit component 1120.

The integrated circuit component 1120 may be a packaged or unpacked integrated circuit product that includes one or more integrated circuit dies (e.g., the die 902 of FIG. 9, the integrated circuit device 1000 of FIG. 10) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1120, a single monolithic integrated circuit die comprises solder bumps attached to contacts on the die. The solder bumps allow the die to be directly attached to the interposer 1104. The integrated circuit component 1120 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1120 can comprise one or more additional active or passive devices such as capacitors, decoupling capacitors, resistors, inductors, fuses, diodes, transformers, sensors, electrostatic discharge (ESD) devices and memory devices.

In embodiments where the integrated circuit component 1120 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1104 may spread connections to a wider pitch or reroute a connection to a different connection. For example, the interposer 1104 may couple the integrated circuit component 1120 to a set of ball grid array (BGA) conductive contacts of the coupling components 1116 for coupling to the circuit board 1102. In the embodiment illustrated in FIG. 11, the integrated circuit component 1120 and the circuit board 1102 are attached to opposing sides of the interposer 1104; in other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through hole vias 1110-1 (that extend from a first face 1150 of the interposer 1104 to a second face 1154 of the interposer 1104), blind vias 1110-2 (that extend from the first or second faces 1150 or 1154 of the interposer 1104 to an internal metal layer), and buried vias 1110-3 (that connect internal metal layers).

In some embodiments, the interposer 1104 can comprise a silicon interposer. Through silicon vias (TSV) extending through the silicon interposer can connect connections on a first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art. In embodiments where the interposer is a non-printed circuit board

The integrated circuit device assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The integrated circuit device assembly 1100 illustrated in FIG. 11 includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

FIG. 12 is a block diagram of an example electrical device 1200 that may include one or more of the embodiments disclosed herein. For example, any suitable ones of the components of the electrical device 1200 may include one or more of the integrated circuit device assemblies 1100, integrated circuit components 1120, integrated circuit devices 1000, or integrated circuit dies 902 disclosed herein. A number of components are illustrated in FIG. 12 as included in the electrical device 1200, but any one or more of these components may be omitted or duplicated, as suitable for the application. In some embodiments, some or all of the components included in the electrical device 1200 may be attached to one or more motherboards mainboards, or system boards. In some embodiments, one or more of these components are fabricated onto a single system-on-a-chip (SoC) die.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include one or more processor units 1202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1200 can comprise one or more processor units 1202 that are heterogeneous or asymmetric to another processor unit 1202 in the electrical device 1200. There can be a variety of differences between the processing units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electrical device 1200.

In some embodiments, the electrical device 1200 may include a communication component 1212 (e.g., one or more communication components). For example, the communication component 1212 can manage wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electrical device 1200 may include an antenna 1222 to facilitate wireless communications and/or to receive other wireless communications (such as AM or FM radio transmissions).

In some embodiments, the communication component 1212 may manage wired communications, such as electrical, optical, or any other suitable communication protocols (e.g., IEEE 802.3 Ethernet standards). As noted above, the communication component 1212 may include multiple communication components. For instance, a first communication component 1212 may be dedicated to shorter-range wireless communications such as Wi-Fi or Bluetooth, and a second communication component 1212 may be dedicated to longer-range wireless communications such as global positioning system (GPS), EDGE, GPRS, CDMA, WiMAX, LTE, EV-DO, or others. In some embodiments, a first communication component 1212 may be dedicated to wireless communications, and a second communication component 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such speakers, headsets, or earbuds.

The electrical device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System (GNSS) device 1218 (or corresponding interface circuitry, as discussed above), such as a Global Positioning System (GPS) device. The GNSS device 1218 may be in communication with a satellite-based system and may determine a geolocation of the electrical device 1200 based on information received from one or more GNSS satellites, as known in the art.

The electrical device 1200 may include another output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include another input device 1220 (or corresponding interface circuitry, as discussed above). Examples of the other input device 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data. In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is an apparatus comprising: a first integrated circuit component; a second integrated circuit component; and an electrical interconnect coupling the first integrated circuit component and the second integrated circuit component, wherein the interconnect comprises one or more spintronic logic devices whose output signal is based on a spin-orbit effect of one or more materials of the device.

Example 2 includes the subject matter of Example 1, wherein states of the spintronic logic devices are encoded through a magnetization of one or more ferromagnetic materials of the devices.

Example 3 includes the subject matter of Example 1 or 2, wherein the spintronic logic devices are magnetoelectric spin orbit (MESO) logic devices.

Example 4 includes the subject matter of Example 1, wherein each spintronic logic device comprises: an electrically conductive layer; a ferromagnetic layer; a magnetoelectric layer disposed at least partially between the electrically conductive layer and the ferromagnetic layer; a spin orbit coupling (SOC) material; and a non-magnetic electrical conductor at least partially between the SOC material and the ferromagnetic layer.

Example 5 includes the subject matter of Example 1, wherein each spintronic logic device comprises: an electrically conductive layer; a first ferromagnetic layer; a second ferromagnetic layer; a magnetoelectric layer disposed at least partially between the electrically conductive layer and the first ferromagnetic layer; an insulating layer between the first ferromagnetic layer and the second ferromagnetic layer; a spin orbit coupling (SOC) material; and a non-magnetic electrical conductor at least partially between the SOC material and the second ferromagnetic layer.

Example 5.5 includes the subject matter of Example 5, wherein the electrically conductive layer is a first electrically conductive layer, the apparatus further comprises a second electrically conductive layer, and the first ferromagnetic layer and the magnetoelectric layer are between the first electrically conductive layer and the second electrically conductive layer.

Example 6 includes the subject matter of Example 1, wherein states of the spintronic logic devices are encoded through a polarization of one or more ferroelectric materials of the device.

Example 7 includes the subject matter of Example 1 or 5, wherein the spintronic logic devices are ferroelectric spin orbit logic (FSOL) devices.

Example 8 includes the subject matter of any one of Examples 1 or 6-7, wherein each spintronic logic device comprises: a first electrically conductive layer; a layer comprising a ferroelectric material (FE layer) on the first electrically conductive layer; a second electrically conductive layer on the FE layer; and a spin orbit coupling (SOC) stack including a first layer (SOC1 layer) including a first SOC material, and a second layer (SOC2 layer) including a second SOC material, the SOC1 layer adjacent the FE layer.

Example 9 includes the subject matter of any one of Examples 1-8, wherein the interconnect comprises plurality of spintronic logic devices.

Example 10 includes the subject matter of Example 9, wherein the interconnect comprises a plurality of n-channel transistors, each n-channel transistor connected to a respective spintronic logic device to provide a supply current to the spintronic logic device.

Example 11 includes the subject matter of any one of Examples 1-10, wherein the first integrated circuit component is a processor core, and the second integrated circuit component is a cache or graphics processing circuitry.

Example 12 includes a processor comprising: one or more processor cores; one or more cache units; and an interconnect coupling the processor cores and the cache units, the interconnect comprising a plurality of spintronic logic devices whose output signal is based on a spin-orbit effect of one or more materials of the device.

Example 13 includes the subject matter of Example 12, wherein states of the spintronic logic devices are encoded through a magnetization of one or more ferromagnetic materials of the devices.

Example 14 includes the subject matter of Example 12 or 13, wherein the spintronic logic devices are magnetoelectric spin orbit (MESO) logic devices.

Example 15 includes the subject matter of Example 12, wherein states of the spintronic logic devices are encoded through a polarization of one or more ferroelectric materials of the device.

Example 16 includes the subject matter of Example 12 or 15, wherein the spintronic logic devices are ferroelectric spin orbit logic (FSOL) devices.

Example 17 includes the subject matter of any one of Examples 12-16, wherein the interconnect comprises a plurality of n-channel transistors, each n-channel transistor connected to a respective spintronic logic device to provide a supply current to the spintronic logic device.

Example 18 includes the subject matter of any one of Examples 12-17, further comprising one or more of graphics processing circuitry, input-output (TO) circuitry, memory controller circuitry, and display controller circuitry coupled to the interconnect.

Example 19 includes a system comprising: memory; and a processor comprising: one or more processor cores; one or more cache units; and an interconnect coupling the processor cores and the cache units, the interconnect comprising one or more spintronic logic devices whose output signal is based on a spin-orbit effect of one or more materials of the device.

Example 20 includes the subject matter of Example 19, wherein states of the spintronic logic devices are encoded through a magnetization of one or more ferromagnetic materials of the devices

Example 21 includes the subject matter of Example 20, wherein the spintronic logic devices are magnetoelectric spin orbit (MESO) logic devices.

Example 22 includes the subject matter of Example 19, wherein states of the spintronic logic devices are encoded through a polarization of one or more ferroelectric materials of the device.

Example 23 includes the subject matter of Example 22, wherein the spintronic logic devices are electric ferroelectric spin orbit logic (FSOL) devices.

Example 24 includes the subject matter of any one of Examples 19-23, wherein the interconnect comprises a plurality of n-channel transistors, each n-channel transistor connected to a respective spintronic logic device to provide a supply current to the spintronic logic device.

Example 25 includes a system comprising any one of Examples 1-18.

Example 26 includes any one of Examples 1-25, wherein the interconnect does not include complementary metal oxide semiconductor (CMOS) devices.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An apparatus comprising:
a first integrated circuit component;
a second integrated circuit component; and
an electrical interconnect coupling the first integrated circuit component and the second integrated circuit component, wherein the interconnect comprises one or more spintronic logic devices whose output signal is based on a spin-orbit effect of one or more materials of the device.

2. The apparatus of claim 1, wherein states of the spintronic logic devices are encoded through a magnetization of one or more ferromagnetic materials of the devices.

3. The apparatus of claim 1, wherein the spintronic logic devices are magnetoelectric spin orbit (MESO) logic devices.

4. The apparatus of claim 1, wherein each spintronic logic device comprises:
an electrically conductive layer;
a ferromagnetic layer;
a magnetoelectric layer disposed at least partially between the electrically conductive layer and the ferromagnetic layer;
a spin orbit coupling (SOC) material; and
a non-magnetic electrical conductor at least partially between the SOC material and the ferromagnetic layer.

5. The apparatus of claim 1, wherein each spintronic logic device comprises:
an electrically conductive layer;
a first ferromagnetic layer;
a second ferromagnetic layer;
a magnetoelectric layer disposed at least partially between the electrically conductive layer and the first ferromagnetic layer;
an insulating layer between the first ferromagnetic layer and the second ferromagnetic layer;
a spin orbit coupling (SOC) material; and
a non-magnetic electrical conductor at least partially between the SOC material and the second ferromagnetic layer.

6. The apparatus of claim 5, wherein the electrically conductive layer is a first electrically conductive layer, the apparatus further comprises a second electrically conductive layer, and the first ferromagnetic layer and the magnetoelectric layer are between the first electrically conductive layer and the second electrically conductive layer.

7. The apparatus of claim 1, wherein states of the spintronic logic devices are encoded through a polarization of one or more ferroelectric materials of the device.

8. The apparatus of claim 1, wherein the spintronic logic devices are ferroelectric spin orbit logic (FSOL) devices.

9. The apparatus of claim 1, wherein each spintronic logic device comprises:
a first electrically conductive layer;
a layer comprising a ferroelectric material (FE layer) on the first electrically conductive layer;
a second electrically conductive layer on the FE layer; and
a spin orbit coupling (SOC) stack including a first layer (SOC1 layer) including a first SOC material, and a second layer (SOC2 layer) including a second SOC material, the SOC1 layer adjacent the FE layer.

10. The apparatus of claim 1, wherein the interconnect comprises plurality of spintronic logic devices.

11. The apparatus of claim 10, wherein the interconnect comprises a plurality of n-channel transistors, each n-channel transistor connected to a respective spintronic logic device to provide a supply current to the spintronic logic device.

12. The apparatus of claim 1, wherein the first integrated circuit component is a processor core, and the second integrated circuit component is a cache or graphics processing circuitry.

13. A processor comprising:
one or more processor cores;
one or more cache units; and
an interconnect coupling the processor cores and the cache units, the interconnect comprising a plurality of spintronic logic devices whose output signal is based on a spin-orbit effect of one or more materials of the device.

14. The processor of claim 13, wherein states of the spintronic logic devices are encoded through a magnetization of one or more ferromagnetic materials of the devices.

15. The processor of claim 13, wherein the spintronic logic devices are magnetoelectric spin orbit (MESO) logic devices.

16. The processor of claim 13, wherein states of the spintronic logic devices are encoded through a polarization of one or more ferroelectric materials of the device.

17. The processor of claim 13, wherein the spintronic logic devices are ferroelectric spin orbit logic (FSOL) devices.

18. The processor of claim 13, wherein the interconnect comprises a plurality of n-channel transistors, each n-channel transistor connected to a respective spintronic logic device to provide a supply current to the spintronic logic device.

19. The processor of claim 13, further comprising one or more of graphics processing circuitry, input-output (TO) circuitry, memory controller circuitry, and display controller circuitry coupled to the interconnect.

20. A system comprising:
memory; and
a processor comprising:
one or more processor cores;
one or more cache units; and
an interconnect coupling the processor cores and the cache units, the interconnect comprising one or more spintronic logic devices whose output signal is based on a spin-orbit effect of one or more materials of the device.

21. The system of claim 20, wherein states of the spintronic logic devices are encoded through a magnetization of one or more ferromagnetic materials of the devices.

22. The system of claim 21, wherein the spintronic logic devices are magnetoelectric spin orbit (MESO) logic devices.

23. The system of claim 20, wherein states of the spintronic logic devices are encoded through a polarization of one or more ferroelectric materials of the device.

24. The system of claim 23, wherein the spintronic logic devices are electric ferroelectric spin orbit logic (FSOL) devices.

25. The system of claim 20, wherein the interconnect comprises a plurality of n-channel transistors, each n-channel transistor connected to a respective spintronic logic device to provide a supply current to the spintronic logic device.
